(19) United States
(12) Patent Application Publication
(10) Pub. No.: US 2022/0395867 A1
(43) Pub. Date: Dec. 15, 2022

(54) SUBSTRATE CLEANING DEVICE

(71) Applicant: SCREEN HOLDINGS CO., LTD., Kyoto (JP)

(72) Inventors: Tomoyuki SHINOHARA, Kyoto-shi (JP); Yoshifumi OKADA, Kyoto-shi (JP); Nobuaki OKITA, Kyoto-shi (JP); Takashi SHINOHARA, Kyoto-shi (JP); Junichi ISHII, Kyoto-shi (JP); Kazuki NAKAMURA, Kyoto-shi (JP); Takuma TAKAHASHI, Kyoto-shi (JP)

(21) Appl. No.: 17/836,118

(22) Filed: Jun. 9, 2022

(30) Foreign Application Priority Data
Jun. 11, 2021 (JP) 2021-098099

(51) Int. Cl. B08B 3/02; B08B 1/00

(52) U.S. Cl. CPC B08B 3/024; B08B 1/002

(57) ABSTRACT

A first cleaner cleans an upper surface of a substrate by scanning above the substrate to pass through a first point in an outer edge of the substrate in a plan view. A second cleaner cleans an outer peripheral end of the substrate by coming into contact with a second point in the outer edge of the substrate in a plan view. A virtual first straight line passing through the first point and the second point and a virtual second straight line passing through a center of the substrate and is parallel to the first straight line are defined. A third cleaner is arranged below the substrate and opposite to the first cleaner and the second cleaner with the second straight line located between the third cleaner, and the first cleaner and the second cleaner, and cleans a lower surface of the substrate.

### BACKGROUND

### Technical Field

The present invention relates to a substrate cleaning device that cleans a substrate.

### Description of Related Art

A substrate processing apparatus is used to perform various processes on various substrates such as a substrate for an FPD (Flat Panel Display) that is used for a liquid crystal display device, an organic EL (Electro Luminescence) display device or the like, a semiconductor substrate, a substrate for an optical disc, a substrate for a magnetic disc, a substrate for a magneto-optical disc, a substrate for a photomask, a ceramic substrate or a substrate for a solar cell. A substrate cleaning device is used to clean a substrate.

For example, a substrate cleaning device described in JP 5904169 B2 includes two suction pads for holding a back-surface peripheral portion of a wafer, a spin chuck for holding a back-surface center portion of the wafer and a brush for cleaning a back surface of the wafer. The two suction pads hold the wafer and move in a transverse direction.

In this state, the back-surface center portion of the wafer is cleaned by the brush. Thereafter, the spin chuck receives the wafer from the suction pads. Further, the spin chuck rotates while holding the back-surface center portion of the wafer. In this state, the back-surface peripheral portion of the wafer is cleaned by the brush.

### SUMMARY

In the substrate cleaning device described in JP 5904169 B2, when not only the back surface of a substrate but also the front surface of the substrate is to be cleaned, it is necessary to transport the substrate to another cleaning device for cleaning the front surface of the substrate. This reduces a throughput and increases a footprint of the entire system for substrate cleaning. Therefore, a substrate cleaning device that can efficiently clean a substrate while preventing an increase in size is desired.

An object of the present invention is to provide a substrate cleaning device that can efficiently clean a substrate while preventing an increase in size.

(1) A substrate cleaning device according to one aspect of the present invention includes a substrate holder that holds a circular substrate in a horizontal attitude, a first cleaner that cleans an upper surface of the substrate by scanning above the substrate to pass through a first point in an outer edge of the substrate in a plan view, a second cleaner that cleans an outer peripheral end of the substrate by coming into contact with a second point in the outer edge of the substrate in a plan view, and a third cleaner that cleans a lower surface of the substrate, wherein a virtual first line that passes through the first point and the second point and a virtual second straight line that passes through a center of the substrate and is parallel to the first straight line, and the third cleaner is arranged below the substrate and opposite to the first cleaner and the second cleaner with the second straight line located between the third cleaner, and the first cleaner and the second cleaner.

In this substrate cleaning device, when the substrate is cleaned, the first cleaner, the second cleaner and the third cleaner are arranged to be relatively largely spaced apart from one another. Therefore, even in a case in which the upper surface, the outer peripheral end and the lower surface of the substrate are respectively cleaned by the first cleaner, the second cleaner and the third cleaner at the same time, contaminants generated from any one of the cleaners hardly adhere to another cleaner. Therefore, it is not necessary to provide a plurality of devices that respectively clean a plurality of portions of the substrate, and it is not necessary to move the substrate among the plurality of devices either. As a result, it is possible to efficiently clean the substrate while preventing an increase in size of the substrate cleaning device.

(2) A virtual third straight line extending from a center of the substrate to a geometric center of the third cleaner in a plan view and a third point in an outer edge of the substrate through which the third straight line passes in a plan view may further be defined, and the first cleaner, the second cleaner and the third cleaner may be arranged such that the center of the substrate is located in a triangular region having the first point, the second point and the third point as vertexes. In this case, when the substrate is cleaned, the first cleaner, the second cleaner and the third cleaner are largely spaced apart from one another. Thus, contaminants generated from any of the cleaners can be prevented from adhering to another cleaner.

(3) A virtual fourth straight line extending from a center of the substrate toward the first point in a plan view and a virtual fifth straight line extending from the center of the substrate toward the second point in a plan view may further be defined, and each of a first angle between the third straight line and the fourth straight line and a second angle between the fourth straight line and the fifth straight line and a third angle between the fifth straight line and the third straight line may be equal to or larger than 80 degrees. In this case, when the substrate is cleaned, the first cleaner, the second cleaner and the third cleaner are more largely spaced apart from one another. Thus, contaminants generated from any one of the cleaners can be more reliably prevented from adhering to another cleaner.

(4) Each of the first angle, the second angle and the third angle may be equal to or larger than 90 degrees. In this case, when the substrate is cleaned, the first cleaner, the second cleaner and the third cleaner are even more largely spaced apart from one another. Thus, contaminants generated from any one of the cleaners can be even more reliably prevented from adhering to another cleaner.

(5) The first angle may be larger than the second angle. In this case, when the substrate is cleaned, because the first cleaner and the third cleaner are relatively largely spaced apart from each other, even in a case in which the third cleaner is relatively large, contaminants generated from one of the first cleaner and the third cleaner do not adhere to the other one. Therefore, the lower surface of the substrate can be more efficiently cleaned.

(6) The third angle may be larger than the second angle. In this case, when the substrate is cleaned, because the second cleaner and the third cleaner are relatively largely spaced apart from each other, even in a case in which the third cleaner is relatively large, contaminants generated from one of the second cleaner and the third cleaner do not adhere to the other one. Therefore, the lower surface of the substrate can be more efficiently cleaned.

(7) The first cleaner may clean an upper surface of the substrate by scanning from a center of the substrate toward the first point in a plan view. In this case, contaminants generated from the first cleaner hardly adhere to the second cleaner or the third cleaner. Similarly, contaminants generated from the second cleaner or the third cleaner hardly adhere to the first cleaner. Therefore, the upper surface of the substrate can be more efficiently cleaned with a simple configuration.

(8) Each of the substrate holder and the third cleaner may have a circular outer shape, and a diameter of the third cleaner may be larger than a diameter of the substrate holder. In this case, the lower surface of the substrate can be more efficiently cleaned by the relatively large third cleaner.

(9) The third cleaner may have a circular outer shape, and a diameter of the third cleaner may be larger than ⅓ of a diameter of the substrate. In this case, the lower surface of the substrate can be more efficiently cleaned by the relatively large third cleaner.

Other features, elements, characteristics, and advantages of the present disclosure will become more apparent from the following description of preferred embodiments of the present disclosure with reference to the attached drawings.

### BRIEF DESCRIPTION OF THE DRAWING

FIG. 1 is a schematic plan view of a substrate cleaning device according to one embodiment of the present invention;

FIG. 2 is an external perspective view showing the inner configuration of the substrate cleaning device of FIG. 1;

FIG. 3 is a block diagram showing the configuration of a control system of the substrate cleaning device of FIG. 1;

FIG. 4 is a plan view showing the positional relationship among cleaners;

FIG. 5 is a plan view showing the more preferable positional relationship among the cleaners;

FIG. 6 is a plan view showing the even more preferable positional relationship among the cleaners;

FIG. 7 is a schematic diagram for explaining the schematic operation of the substrate cleaning device of FIG. 1;

FIG. 8 is a schematic diagram for explaining the schematic operation of the substrate cleaning device of FIG. 1;

FIG. 9 is a schematic diagram for explaining the schematic operation of the substrate cleaning device of FIG. 1;

FIG. 10 is a schematic diagram for explaining the schematic operation of the substrate cleaning device of FIG. 1;

FIG. 11 is a schematic diagram for explaining the schematic operation of the substrate cleaning device of FIG. 1;

FIG. 12 is a schematic diagram for explaining the schematic operation of the substrate cleaning device of FIG. 1;

FIG. 13 is a schematic diagram for explaining the schematic operation of the substrate cleaning device of FIG. 1;

FIG. 14 is a schematic diagram for explaining the schematic operation of the substrate cleaning device of FIG. 1;

FIG. 15 is a schematic diagram for explaining the schematic operation of the substrate cleaning device of FIG. 1;

FIG. 16 is a schematic diagram for explaining the schematic operation of the substrate cleaning device of FIG. 1;

FIG. 17 is a schematic diagram for explaining the schematic operation of the substrate cleaning device of FIG. 1; and

FIG. 18 is a schematic diagram for explaining the schematic operation of the substrate cleaning device of FIG. 1.

### DETAILED DESCRIPTION

A substrate cleaning device according to embodiments of the present invention will be described below with reference to the drawings. In the following description, a substrate refers to a semiconductor substrate, a substrate for an FPD (Flat Panel Display) such as a liquid crystal display device or an organic EL (Electro Luminescence) display device, a substrate for an optical disc, a substrate for a magnetic disc, a substrate for a magneto-optical disc, a substrate for a photomask, a ceramic substrate, a substrate for a solar battery, or the like. Further, as for a substrate to be used in the present embodiment, at least part of the substrate has a circular outer periphery. For example, the outer periphery except for a notch for positioning is circular.

(1) Configuration of Substrate Processing Apparatus

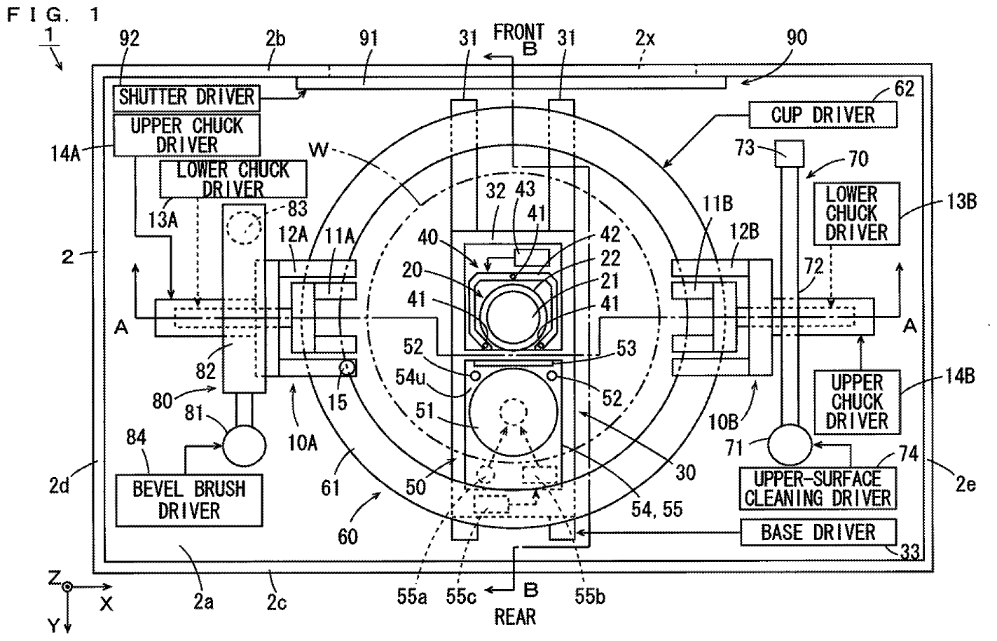

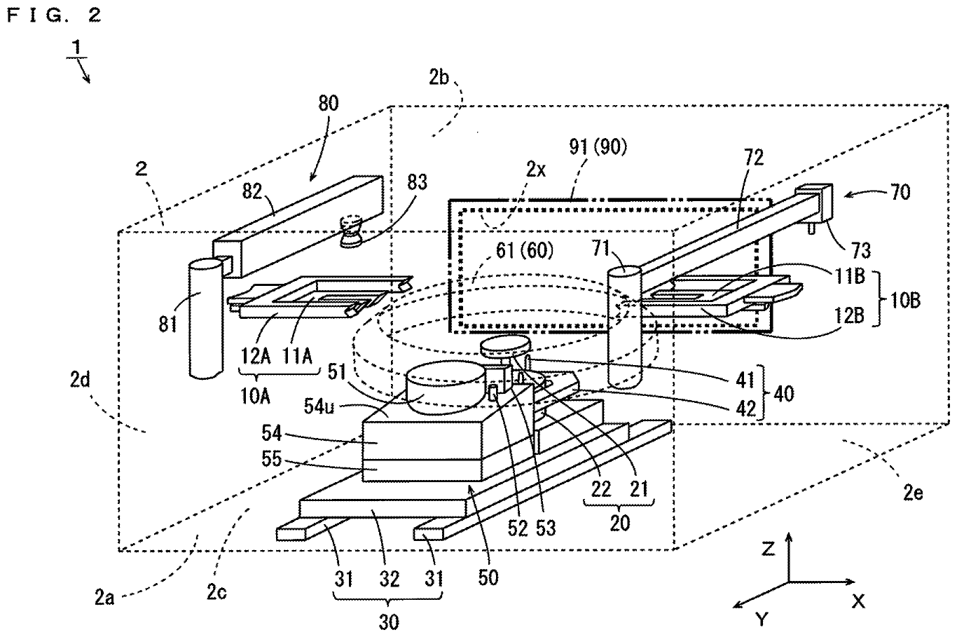

FIG. 1 is a schematic plan view of a substrate cleaning device according to one embodiment of the present invention. FIG. 2 is an external perspective view showing the inner configuration of the substrate cleaning device 1 of FIG. 1. In the substrate cleaning device 1 according to the present embodiment, X, Y and Z directions orthogonal to one another are defined for the clarity of a positional relationship. In FIG. 1 and the subsequent drawings, the X, Y and Z directions are suitably indicated by arrows. The X and Y directions are orthogonal to each other within a horizontal plane, and the Z direction corresponds to a vertical direction.

As shown in FIG. 1, the substrate cleaning device 1 includes upper holding devices 10A, 10B, a lower holding device 20, a base device 30, a receiving-transferring device 40, a lower-surface cleaning device 50, a cup device 60, an upper-surface cleaning device 70, an end-portion cleaning device 80 and an opening-closing device 90. These constituent elements are provided in a unit casing 2. In FIG. 2, the unit casing 2 is indicated by the dotted lines.

The unit casing 2 has a rectangular bottom surface portion 2a, and four sidewall portions 2b, 2c, 2d, 2e extending upwardly from four sides of the bottom surface portion 2a. The sidewall portions 2b, 2c are opposite to each other, and the sidewall portions 2d, 2e are opposite to each other. A rectangular opening is formed in the center portion of the sidewall portion 2b. This opening is an inlet-outlet port 2x for a substrate W and is used when the substrate W is carried into and carried out from the unit casing 2. In FIG. 2, the inlet-outlet port 2x is indicated by the thick dotted lines. In the following description, a direction directed outwardly of the unit casing 2 in the Y direction from the inside of the unit casing 2 through the inlet-outlet port 2x (the direction directed from the sidewall portion 2c toward the sidewall portion 2b) is referred to as forward, and its opposite direction (the direction directed from the sidewall portion 2b toward the sidewall portion 2c) is referred to as rearward.

The opening-closing device 90 is provided in a portion in which the inlet-outlet port 2x is formed and its vicinal region in the sidewall portion 2b. The opening-closing device 90 includes a shutter 91 that is configured to be capable of opening and closing the inlet-outlet port 2x and a shutter driver 92 that drives the shutter 91. In FIG. 2, the shutter 91 is indicated by the thick two-dots and dash lines. The shutter driver 92 drives the shutter 91 to open the inlet-outlet port 2x when a substrate W is carried into and carried out from the substrate cleaning device 1. Further, the shutter driver 92 drives the shutter 91 to close the inlet-outlet port 2x when a substrate W is cleaned in the substrate cleaning device 1.

The base device 30 is provided in the center portion of the bottom surface portion 2a. The base device 30 includes linear guides 31, a mobile base 32 and a base driver 33. The linear guides 31 include two rails and are provided to extend in the Y direction from positions in the vicinity of the sidewall portion 2b to positions in the vicinity of the sidewall portion 2c in a plan view. The mobile base 32 is provided to be movable in the Y direction on the two rails of the linear guides 31. The base driver 33 includes a pulse motor, for example, and moves the mobile base 32 in the Y direction on the linear guides 31.

The lower holding device 20 and the lower-surface cleaning device 50 are provided on the mobile base 32 to be arranged in the Y direction. The lower holding device 20 includes a suction holder 21 and a suction holding driver 22. The suction holder 21 is a so-called spin chuck, has a circular suction surface that can hold a lower surface of a substrate W by suction and is configured to be rotatable about an axis extending in the up-and-down direction (the axis extending in the Z direction). In the following description, a region that is to be sucked by the suction surface of the suction holder 21 in the lower surface of the substrate W when the substrate W is held by suction by the suction holder 21 is referred to as a lower-surface center region. On the other hand, a region, surrounding the lower-surface center region, in the lower surface of the substrate W is referred to as a lower-surface outer region.

The suction holding driver 22 includes a motor. The motor of the suction holding driver 22 is provided on the mobile base 32 such that its rotation shaft projects upwardly. The suction holder 21 is provided at the upper end portion of the rotation shaft of the suction holding driver 22. Further, in the rotation shaft of the suction holding driver 22, a suction path for holding a substrate W by suction in the suction holder 21 is formed. The suction path is connected to a suction device (not shown). The suction holding driver 22 rotates the suction holder 21 about the above-mentioned rotation shaft.

On the mobile base 32, the receiving-transferring device 40 is further provided in the vicinity of the lower holding device 20. The receiving-transferring device 40 includes a plurality (three in the present example) of support pins 41, a pin coupling member 42 and a pin lifting-lowering driver 43. The pin coupling member 42 is formed to surround the suction holder 21 in a plan view and couples the plurality of support pins 41 to one another. The plurality of support pins 41 extend upwardly by a certain length from the pin coupling member 42 while being coupled to one another by the pin coupling member 42. The pin lifting-lowering driver 43 lifts or lowers the pin coupling member 42 on the mobile base 32. Thus, the plurality of support pins 41 are lifted or lowered relative to the suction holder 21.

The lower-surface cleaning device 50 includes a lower-surface brush 51, two liquid nozzles 52, a gas injector 53, a lifting-lowering supporter 54, a movement supporter 55, a lower-surface brush rotation driver 55a, a lower-surface brush lifting-lowering driver 55b and a lower-surface brush movement driver 55c. The movement supporter 55 is provided to be movable in the Y direction with respect to the lower holding device 20 in a certain region on the mobile base 32. As shown in FIG. 2, the lifting-lowering supporter 54 is provided on the movement supporter 55 to be liftable and lowerable. The lifting-lowering supporter 54 has an upper surface 54u that is inclined downwardly in a direction away from the suction holder 21 (rearwardly in the present example).

As shown in FIG. 1, the lower-surface brush 51 has a circular outer shape in a plan view and is formed to be relatively large in the present embodiment. Specifically, the diameter of the lower-surface brush 51 is larger than the diameter of the suction surface of the suction holder 21 and is 1.3 times of the diameter of the suction surface of the suction holder 21, for example. Further, the diameter of the lower-surface brush 51 is larger than ⅓ of the diameter of a substrate W and smaller than ½ of the diameter of a substrate W. The diameter of a substrate W is 300 mm, for example.

The lower-surface brush 51 has a cleaning surface that can come into contact with the lower surface of a substrate W. Further, the lower-surface brush 51 is attached to the upper surface 54u of the lifting-lowering supporter 54 such that the cleaning surface is directed upwardly and the cleaning surface is rotatable about an axis extending in the up-and-down direction through the center of the cleaning surface.

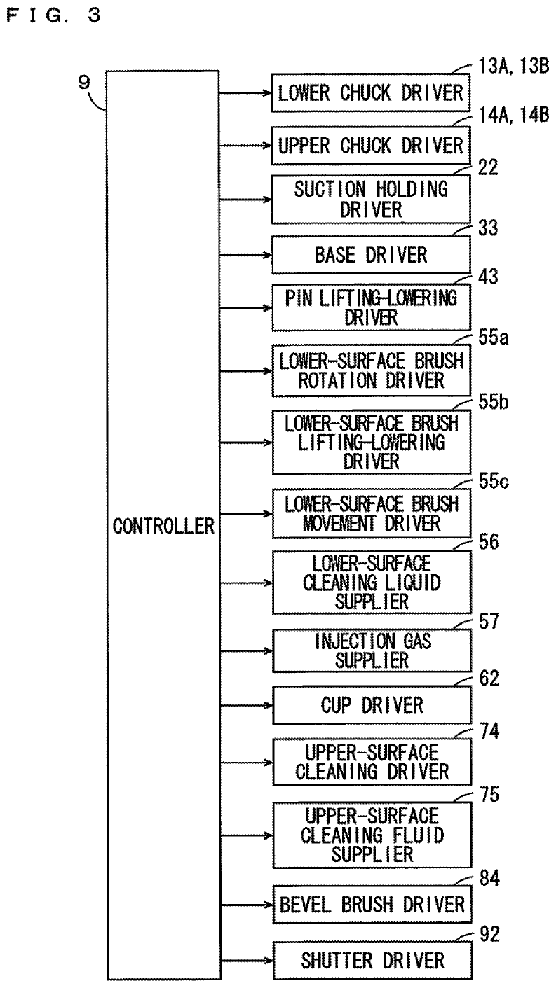

Each of the two liquid nozzles 52 is attached to the upper surface 54u of the lifting-lowering supporter 54 to be located in the vicinity of the lower-surface brush 51. Further, each of the two liquid nozzles 52 is attached to the upper surface 54u such that a liquid discharge port is directed upwardly. A lower-surface cleaning liquid supplier 56 (FIG. 3) is connected to the liquid nozzles 52. The lower-surface cleaning liquid supplier 56 supplies a cleaning liquid to the liquid nozzles 52. When a substrate W is cleaned by the lower-surface brush 51, the liquid nozzles 52 discharge the cleaning liquid supplied from the lower-surface cleaning liquid supplier 56 to the lower surface of the substrate W. In the present embodiment, pure water is used as the cleaning liquid to be supplied to the liquid nozzles 52.

The gas injector 53 is a slit-like gas injection nozzle having a gas injection port extending in one direction. The gas injector 53 is attached to the upper surface 54u of the lifting-lowering supporter 54 to be located between the lower-surface brush 51 and the suction holder 21 in a plan view. Further, the gas injector 53 is attached to the upper surface 54u of the lifting-lowering supporter 54 such that a gas injection port is directed upwardly. An injection gas supplier 57 (FIG. 3) is connected to the gas injector 53. The injection gas supplier 57 supplies gas to the gas injector 53. In the present embodiment, an inert gas such as a nitrogen gas is used as the gas to be supplied to the gas injector 53. The gas injector 53 injects the gas supplied from the injection gas supplier 57 to the lower surface of a substrate W when the substrate W is cleaned by the lower-surface brush 51 and when the lower surface of a substrate W is dried, as described below. In this case, a strip-shaped gas curtain extending in the X direction is formed between the lower-surface brush 51 and the suction holder 21.

The lower-surface brush rotation driver 55a includes a motor, and rotates the lower-surface brush 51 when a substrate W is cleaned by the lower-surface brush 51. The lower-surface brush lifting-lowering driver 55b includes a stepping motor or an air cylinder, and lifts or lowers the lifting-lowering supporter 54 with respect to the movement supporter 55. The lower-surface brush movement driver 55c includes a motor, and moves the movement supporter 55 in the Y direction on the mobile base 32. Here, the position of the lower holding device 20 in the mobile base 32 is fixed. Therefore, when being moved by the lower-surface brush movement driver 55c in the Y direction, the movement supporter 55 is moved relative to the lower holding device 20. In the following description, the position of the lower-surface cleaning device 50 being located closest to the lower holding device 20 on the mobile base 32 is referred to as a proximal position, and the position of the lower-surface cleaning device 50 located farthest from the lower holding device 20 on the mobile base 32 is referred to as a distal position.

The cup device 60 is further provided in the center portion of the bottom surface portion 2a. The cup device 60 includes a cup 61 and a cup driver 62. The cup 61 is provided to surround the lower holding device 20 and the base device 30 in a plan view, and be liftable and lowerable. In FIG. 2, the cup 61 is indicated by the dotted lines. The cup driver 62 moves the cup 61 between a lower cup position and an upper cup position in accordance with which portion of the lower surface of a substrate W is to be cleaned by the lower-surface brush 51. The lower cup position is a height position at which the upper end portion of the cup 61 is located farther downwardly than a substrate W held by suction by the suction holder 21. Further, the upper cup position is a height position at which the upper end portion of the cup 61 is located farther upwardly than the suction holder 21.

At height positions farther upward than the cup 61, the pair of upper holding devices 10A, 10B is provided to be opposite to each other with the base device 30 held therebetween in a plan view. The upper holding device 10A includes a lower chuck 11A, an upper chuck 12A, a lower chuck driver 13A and an upper chuck driver 14A. The upper holding device 10B includes a lower chuck 11 B, an upper chuck 12B, a lower chuck driver 13B and an upper chuck driver 14B.

The lower chucks 11A, 11 B are arranged symmetrically with respect to a vertical plane extending in the Y direction (the front-and-rear direction) through the center of the suction holder 21 in a plan view, and are provided to be movable in the X direction in a common horizontal plane. Each of the lower chucks 11A, 11B has two support pieces that can be support a lower-surface peripheral portion of a substrate W from below the substrate W. The lower chuck drivers 13A, 13B move the lower chucks 11A, 11B such that the lower chucks 11A, 11B are closer to each other or are farther away from each other.

Similarly to the lower chucks 11A, 11B, the upper chucks 12A, 12B are arranged symmetrically with respect to the vertical plane extending in the Y direction (the front-and-rear direction) through the center of the suction holder 21 in a plan view, and are provided to be movable in the X direction in a common horizontal plane. Each of the upper chucks 12A, 12B has two holding pieces that are configured to abut against two portions of the outer peripheral end of a substrate W and be capable of holding the outer peripheral end of the substrate W. The upper chuck drivers 14A, 14B move the upper chucks 12A, 12B such that the upper chucks 12A, 12B are closer to each other or farther away from each other.

As shown in FIG. 1, at a position near one side of the cup 61, the upper-surface cleaning device 70 is provided to be located in the vicinity of the upper holding device 10B in a plan view. The upper-surface cleaning device 70 includes a rotation support shaft 71, an arm 72, a spray nozzle 73 and an upper-surface cleaning driver 74.

The rotation support shaft 71 is supported on the bottom surface portion 2a by the upper-surface cleaning driver 74 to extend in the up-and-down direction, and to be liftable, lowerable and rotatable. As shown in FIG. 2, at a position farther upward than the upper holding device 10B, the arm 72 is provided to extend in the horizontal direction from the upper end portion of the rotation support shaft 71. The spray nozzle 73 is attached to the tip portion of the arm 72.

An upper-surface cleaning fluid supplier 75 (FIG. 3) is connected to the spray nozzle 73. The upper-surface cleaning fluid supplier 75 supplies the cleaning liquid and gas to the spray nozzle 73. In the present embodiment, pure water is used as the cleaning liquid to be supplied to the spray nozzle 73, and an inert gas such as a nitrogen gas is used as the gas to be supplied to the spray nozzle 73. When the upper surface of the substrate W is cleaned, the spray nozzle 73 mixes the cleaning liquid and the gas supplied from the upper-surface cleaning fluid supplier 75 to produce a fluid mixture, and injects the produced fluid mixture downwardly.

The upper-surface cleaning driver 74 includes one or a plurality of pulse motors, an air cylinder and the like, lifts or lowers the rotation support shaft 71, and rotates the rotation support shaft 71. With the above-mentioned configuration, on the upper surface of a substrate W held by suction and rotated by the suction holder 21, the spray nozzle 73 is moved in a circular arc shape. Thus, the entire upper surface of the substrate W can be cleaned.

As shown in FIG. 1, ata position near the other side of the cup 61, the end-portion cleaning device 80 is provided to be located in the vicinity of the upper holding device 10A in a plan view. The end-portion cleaning device 80 includes a rotation support shaft 81, an arm 82, a bevel brush 83 and a bevel brush driver 84.

The rotation support shaft 81 is supported on the bottom surface portion 2a by the bevel brush driver 84 to extend in the up-and-down direction and to be liftable, lowerable and rotatable. As shown in FIG. 2, at a position farther upward than the upper holding device 10A, the arm 82 is provided to extend in the horizontal direction from the upper end portion of the rotation support shaft 81. At the tip portion of the arm 82, the bevel brush 83 is provided to project downwardly and to be rotatable about an axis extending in the up-and-down direction.

In the bevel brush 83, its upper half portion has an inverse trapezoidal shape, and its lower half portion has a trapezoidal shape. With the bevel brush 83, the outer peripheral end of a substrate W can be cleaned with the center portion in the up-and-down direction of the outer peripheral surface.

The bevel brush driver 84 includes one or a plurality of pulse motors, an air cylinder and the like, lifts or lowers the rotation support shaft 81 and rotates the rotation support shaft 81. With the above-mentioned configuration, the center portion of the outer peripheral surface of the bevel brush 83 is brought into contact with the outer peripheral end of a substrate W held by suction and rotated by the suction holder 21. Thus, the entire outer peripheral end of the substrate W can be cleaned.

Here, the bevel brush driver 84 further includes a motor built in the arm 82. The motor rotates the bevel brush 83 provided at the tip portion of the arm 82 about the axis extending in the up-and-down direction. Therefore, when the outer peripheral end of a substrate W is cleaned, a cleaning force of the bevel brush 83 in the outer peripheral end of the substrate W is improved by rotation of the bevel brush 83.

FIG. 3 is a block diagram showing the configuration of a control system of the substrate cleaning device 1 of FIG. 1. A controller 9 of FIG. 3 includes a CPU (Central Processing Unit), a RAM (Random Access Memory), a ROM (Read Only Memory) and a storage device. The RAM is used as a work area for the CPU. The ROM stores a system program. The storage device stores a control program. The operation of each component in the substrate cleaning device 1 is controlled by execution of a substrate cleaning program stored in the storage device on the RAM by the CPU.

As shown in FIG. 3, the controller 9 controls the lower chuck drivers 13A, 13B and the upper chuck drivers 14A, 14B in order to mainly receive a substrate W that is carried into the substrate cleaning device 1 and hold the substrate W at a position above the suction holder 21. Further, the controller 9 mainly controls the suction holding driver 22 in order to hold a substrate W by suction using the suction holder 21 and rotate the substrate W held by suction.

Further, the controller 9 mainly controls the base driver 33 in order to move the mobile base 32 with respect to a substrate W held by the upper holding devices 10A, 10B. Further, the controller 9 controls the pin lifting-lowering driver 43 in order to move a substrate W between a height position of the substrate W held by the upper holding devices 10A, 10B and a height position of the substrate W held by the suction holder 21.

Further, the controller 9 controls the lower-surface brush rotation driver 55a, the lower-surface brush lifting-lowering driver 55b, the lower-surface brush movement driver 55c, the lower-surface cleaning liquid supplier 56 and the injection gas supplier 57 in order to clean the lower surface of a substrate W. Further, the controller 9 controls the cup driver 62 in order to receive the cleaning liquid splashed from a substrate W using the cup 61 when the substrate W held by the suction by the suction holder 21 is cleaned.

Further, the controller 9 controls the upper-surface cleaning driver 74 and the upper-surface cleaning fluid supplier 75 in order to clean the upper surface of a substrate W held by suction by the suction holder 21. Further, the controller 9 controls the bevel brush driver 84 in order to clean the outer peripheral end of a substrate W held by suction by the suction holder 21. Further, the controller 9 controls the shutter driver 92 in order to open and close the inlet-outlet port 2x of the unit casing 2 when a substrate W is carried into and carried out from a substrate cleaning device 1.

(2) Positional Relationship Between Cleaners

In the present embodiment, in the same unit casing 2, cleaning of the upper surface of a substrate W by the spray nozzle 73, cleaning of the outer peripheral end of the substrate W by the bevel brush 83 and cleaning of the lower-surface outer region of the substrate W by the lower-surface brush 51 are performed at the same time. In the following description, each of the spray nozzle 73, the bevel brush 83 and the lower-surface brush 51 is referred to as a cleaner.

Depending on the arrangement of a plurality of cleaners, contaminants generated from any of the cleaners may adhere to another cleaner. In this case, efficiency for cleaning the substrate W is degraded by adherence of contaminants to a substrate W from the cleaner. Therefore, each cleaner is arranged such that influence of interference with one another is reduced.

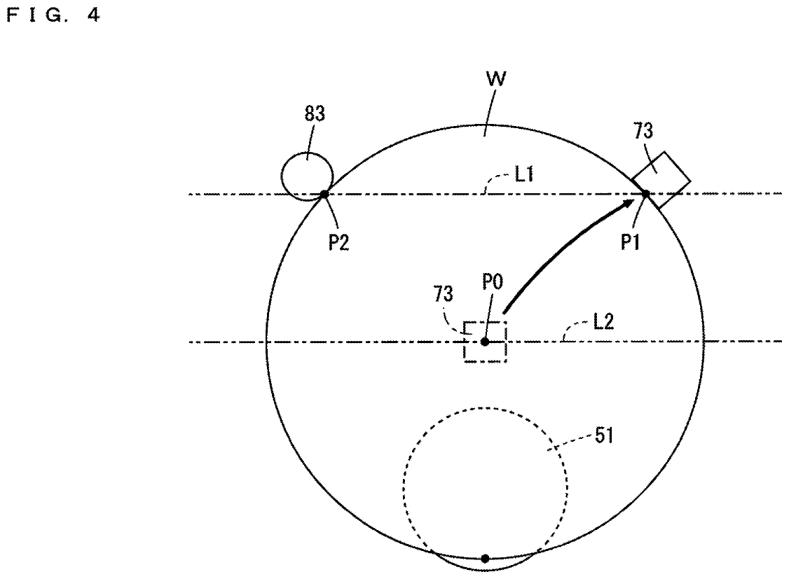

FIG. 4 is a plan view showing the positional relationship among cleaners. As indicated by the one-dot and dash lines in FIG. 4, when the upper surface of the substrate W is cleaned, the spray nozzle 73 is moved to a position above a center P0 of a substrate W by the upper-surface cleaning driver 74 of FIG. 1. Thereafter, as indicated by the thick arrow in FIG. 4, the spray nozzle 73 scans outwardly of the substrate W along the trajectory of a circle while injecting a fluid mixture. At this time, in a plan view, a point in the outer edge of the substrate W that comes into contact with the outer edge of the spray nozzle 73 is referred to as P1.

When the outer peripheral end of a substrate W is cleaned, the bevel brush driver 84 of FIG. 1 brings the bevel brush 83 into contact with the outer peripheral end of the substrate W. In a plan view, a point in the outer edge of the substrate W that comes into with the bevel brush 83 is referred to as P2. Here, the virtual straight line passing through the point P1 and the point P2 is defined as L1. Further, the virtual straight line passing through the center P0 of the substrate W and parallel to the straight line L1 is defined as L2.

When the lower-surface outer region of a substrate W is cleaned, the base driver 33 of FIG. 1 arranges the lower-surface brush 51 below the substrate W and opposite to the spray nozzle 73 and the bevel brush 83 with the straight line L2 located between the lower-surface brush 51, and the spray nozzle 73 and bevel brush 83. While the lower-surface brush 51 is arranged such that its part projects outwardly from the substrate W in the present embodiment as shown in FIG. 4, the embodiment is not limited to this. The lower-surface brush 51 may be arranged such that its outer edge overlaps with the outer edge of the substrate W.

With disposition of the cleaner of FIG. 4, when a substrate W is cleaned, the spray nozzle 73, the bevel brush 83 and the lower-surface brush 51 are relatively largely spaced apart from one another. Therefore, even in a case in which the upper surface, the outer peripheral end and the lower surface of a substrate W are respectively cleaned by the spray nozzle 73, the bevel brush 83 and the lower-surface brush 51 at the same time, contaminants generated from any of the cleaners hardly adhere to another cleaner.

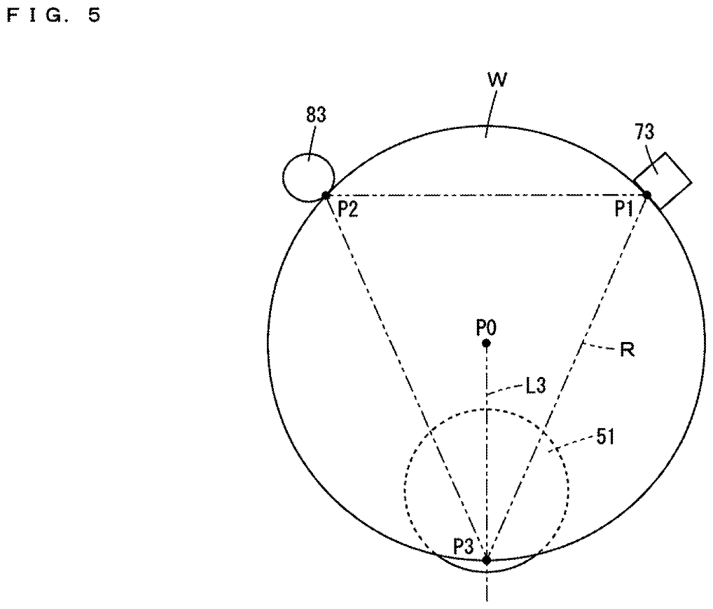

FIG. 5 is a plan view showing the more preferable positional relationship among the cleaners. As shown in FIG. 5, in a plan view, the virtual straight line (half line) extending from the center P0 of a substrate W toward the geometric center of the lower-surface brush 51 is defined as L3. Further, in a plan view, a point in the outer edge of the substrate W through which the straight line L3 passes is defined as P3. In this case, a triangular region R having the point P1, the point P2 and the point P3 as vertexes is formed.

The spray nozzle 73, the bevel brush 83 and the lower-surface brush 51 are preferably arranged such that the center P0 of the substrate W is located in the region R. In this case, when the substrate cleaning device 1 cleans a substrate W, the spray nozzle 73, the bevel brush 83 and the lower-surface brush 51 are largely spaced apart from one another. Therefore, contaminants generated from any of the cleaners can be prevented from adhering to another cleaner.

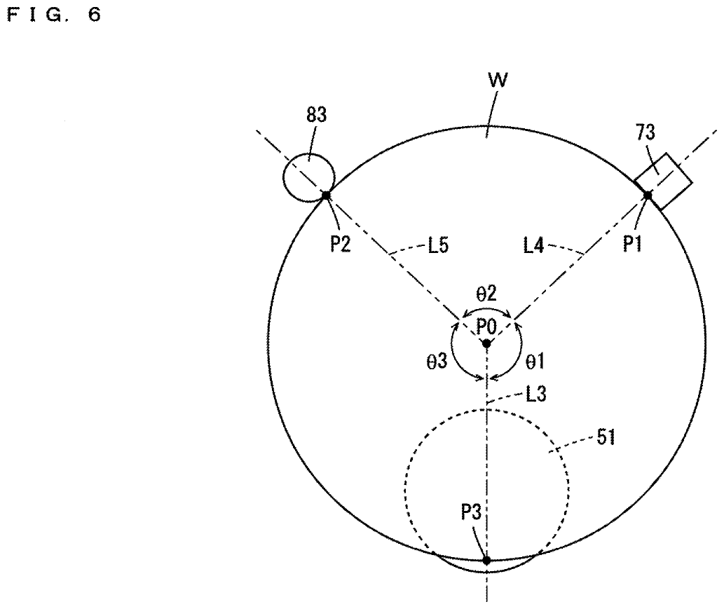

FIG. 6 is a plan view showing the even more preferable positional relationship among the cleaners. As shown in FIG. 6, in a plan view, the virtual straight line (half line) extending from the center of a substrate W toward the point P1 is defined as L4, and the virtual straight line (half line) extending from the center of the substrate W toward the point P2 is defined as L5. Further, the angle between the straight line L3 and the straight line L4 is defined as θ1, the angle between the straight line L4 and the straight line L5 is defined as θ2, and the angle between the straight line L5 and the straight line L3 is defined as θ3. Note that the sum of the angles θ1, θ2 and θ3 is 360 degrees.

Each of the angles θ1, θ2 and θ3 is preferably equal to or larger than 80 degrees.

In this case, when the substrate W is cleaned, the spray nozzle 73, the bevel brush 83 and the lower-surface brush 51 are more largely spaced apart from one another. Thus, contaminants generated from any one of the cleaners can be more reliably prevented from adhering to another cleaner.

Each of the angles θ1, θ2 and θ3 is more preferably equal to or larger than 90 degrees. In this case, the spray nozzle 73, the bevel brush 83 and the lower-surface brush 51 are even more largely spaced apart from one another. Thus, contaminants generated from any one of the cleaners can be even more reliably prevented from adhering to another cleaner.

The angle θ1 is preferably larger than the angle θ2. In this case, because the spray nozzle 73 and the lower-surface brush 51 are relatively largely spaced apart from one another, even in a case in which the lower-surface brush 51 is relatively large, contaminants generated from one of the spray nozzle 73 and the lower-surface brush 51 do not adhere to the other one. Therefore, the lower surface of a substrate W can be more efficiently cleaned by the relatively large lower-surface brush 51.

Even more preferably, the angle θ3 is larger than the angle θ2. In this case, because the bevel brush 83 and the lower-surface brush 51 are relatively largely spaced apart from one another, even in a case in which the lower-surface brush 51 is relatively large, contaminants generated from one of the bevel brush 83 and the lower-surface brush 51 do not adhere to the other one. Therefore, the lower surface of a substrate W can be more efficiently cleaned by the relatively large lower-surface brush 51.

(3) Schematic Operation of Substrate Cleaning Device

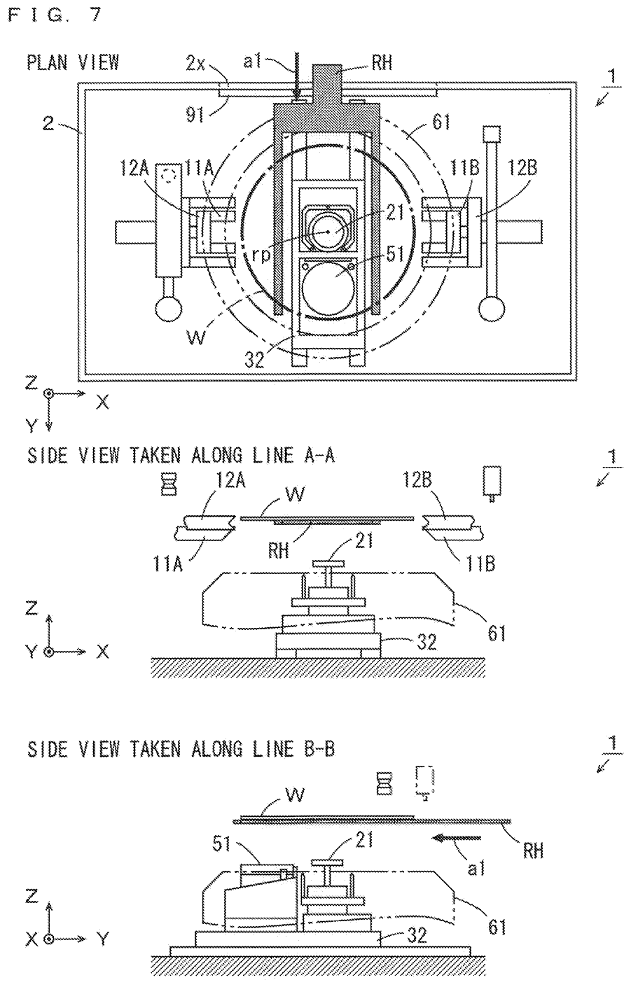

FIGS. 7 to 18 are schematic diagrams for explaining the schematic operation of the substrate cleaning device 1 of FIG. 1. In each of FIGS. 7 to 18, a plan view of the substrate cleaning device 1 is shown in the upper field. Further, a side view of the lower holding device 20 and its peripheral portions as viewed in the Y direction is shown in the middle field, and a side view of the lower holding device 20 and its peripheral portions as viewed in the X direction is shown in the bottom field. The side view in the middle field corresponds to the side view of the substrate cleaning device 1 taken along the line A-A of FIG. 1, and the side view in the bottom field corresponds to the side view of the substrate cleaning device 1 taken along the line B-B of FIG. 1. The expansion and contraction rates of part of the constituent elements are different for the plan view in the upper field and the side views in the middle and bottom fields in order to facilitate understanding of the shape and operation state of each constituent element in the substrate cleaning device 1. Further, in each of FIGS. 7 to 18, the cup 61 is indicated by the two-dots and dash lines, and the outer shape of a substrate W is indicated by the thick one-dot and dash lines.

In an initial state before a substrate W is carried into the substrate cleaning device 1, the inlet-outlet port 2x is closed by the shutter 91 of the opening-closing device 90. Further, as shown in FIG. 1, the lower chucks 11A, 11B are maintained in a state in which the distance between the lower chucks 11A, 11B is sufficiently larger than the diameter of the substrate W. Further, the upper chucks 12A, 12B are also maintained in a state in which the distance between the upper chucks 12A, 12B is sufficiently larger than the diameter of the substrate W. Further, the mobile base 32 of the base device 30 is arranged such that the center of the suction holder 21 is located at the center of the cup 61 in a plan view. The lower-surface cleaning device 50 is arranged in the proximal position on the mobile base 32. In the lifting-lowering supporter 54 of the lower-surface cleaning device 50, the cleaning surface (the upper end portion) of the lower-surface brush 51 is located farther downwardly than the suction holder 21.

Further, in the receiving-transferring device 40, the plurality of support pins 41 are located farther downwardly than the suction holder 21. Further, in the cup device 60, the cup 61 is in the lower cup position. In the following description, the center position of the cup 61 in a plan view is referred to as a plane reference position rp. Further, the position of the mobile base 32 located on the bottom surface portion 2a when the center of the suction holder 21 is in the plane reference position rp in a plan view is referred to as a first horizontal position.

A substrate W is carried into the unit casing 2 of the substrate cleaning device 1. Specifically, the shutter 91 opens the inlet-outlet port 2x immediately before the substrate W is carried in. Thereafter, as indicated by the thick solid arrow al in FIG. 7, a hand (substrate holder) RH of a substrate transporting robot (not shown) carries the substrate W to the substantially center position in the unit casing 2 through the inlet-outlet port 2x. At this time, the substrate W held by the hand RH is located between the lower chuck 11A and the upper chuck 12A, and the lower chuck 11B and the upper chuck 12B as shown in FIG. 7.

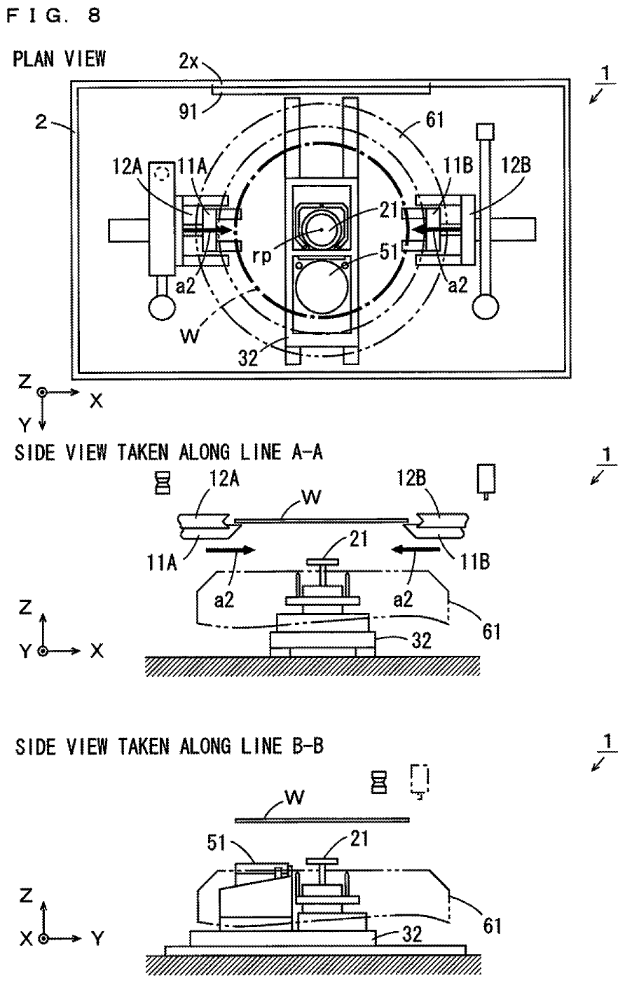

Next, as indicated by the thick solid arrows a2 in FIG. 8, the lower chucks 11A, 11B move closer to each other such that a plurality of support pieces of the lower chucks 11A, 11B are located below the lower-surface peripheral portion of the substrate W. In this state, the hand RH is lowered and exits from the inlet-outlet port 2x. Thus, a plurality of portions of the lower-surface peripheral portion of the substrate W held by the hand RH are supported by the plurality of support pieces of the lower chucks 11A, 11B. After the hand RH exits, the shutter 91 closes the inlet-outlet port 2x.

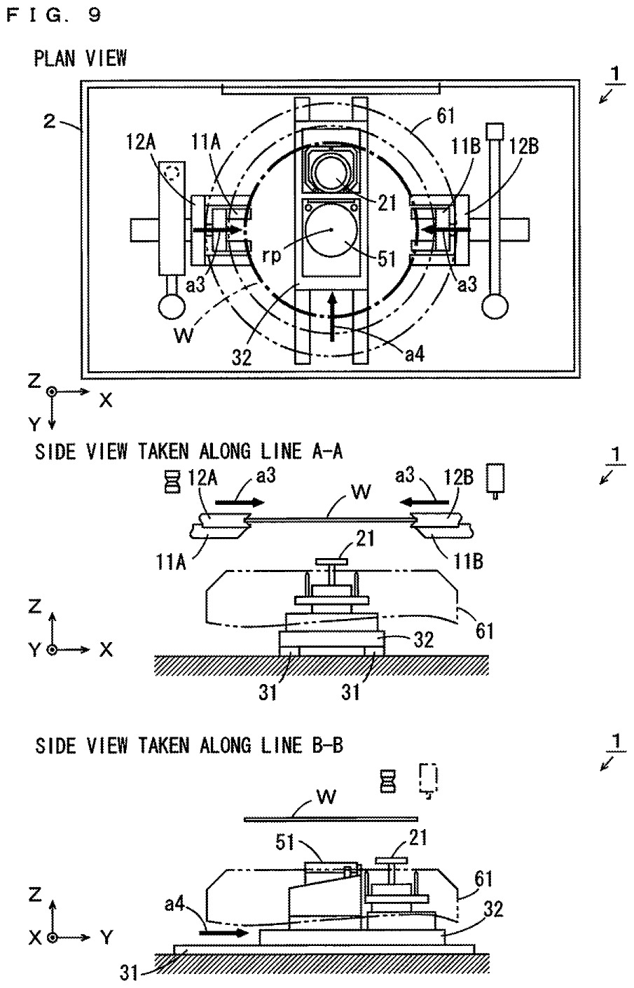

Next, as indicated by the thick solid arrows a3 in FIG. 9, the upper chucks 12A, 12B move closer to each other such that a plurality of holding pieces of the upper chucks 12A, 12B abut against the outer peripheral end of the substrate W. The plurality of holding pieces of the upper chucks 12A, 12B abut against a plurality of portions of the outer peripheral end of the substrate W, whereby the substrate W supported by the lower chucks 11A, 11B is further held by the upper chucks 12A, 12B. Further, as indicated by the thick solid arrow a4 in FIG. 9, the mobile base 32 is moved forwardly from the first horizontal position, such that suction holder 21 deviates from the plane reference position rp by a predetermined distance and the center of the lower-surface brush 51 is located at the plane reference position rp. At this time, the position of the mobile base 32 located on the bottom surface portion 2a is referred to as a second horizontal position.

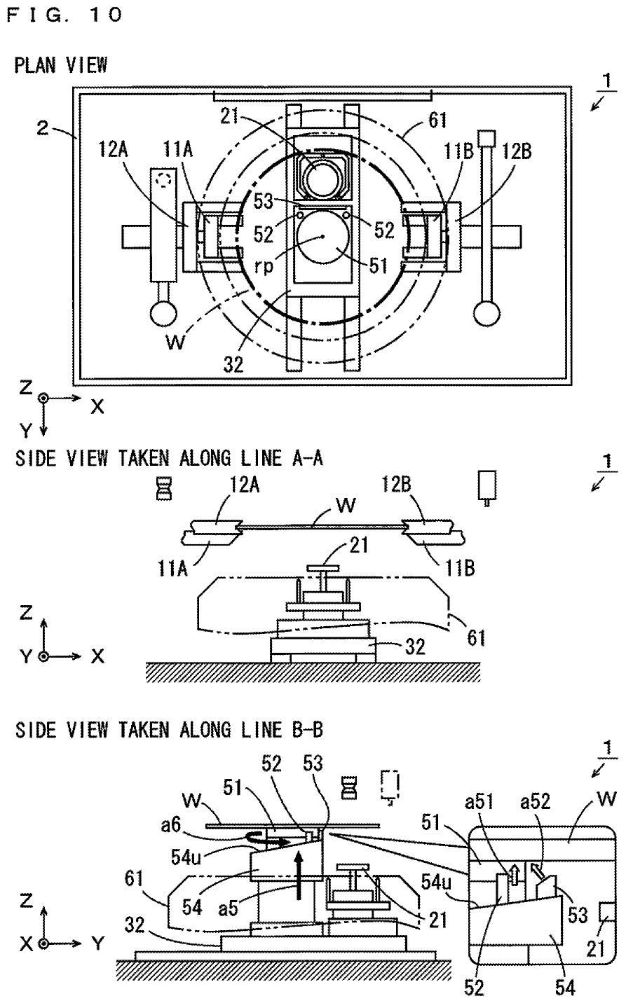

Next, as indicated by the thick solid arrow a5 in FIG. 10, the lifting-lowering supporter 54 is lifted such that the cleaning surface of the lower-surface brush 51 comes into contact with the lower-surface center region of the substrate W. Further, as indicated by the thick solid arrow a6 in FIG. 10, the lower-surface brush 51 is rotated (spins) about the axis extending in the up-and-down direction. Thus, contaminants adhering to the lower-surface center region of the substrate W are physically stripped by the lower-surface brush 51.

In the bottom field in FIG. 10, an enlarged side view of a portion in which the lower-surface brush 51 comes into contact with the lower surface of the substrate W is shown in a balloon. As shown in the balloon, with the lower-surface brush 51 in contact with the substrate W, the liquid nozzle 52 and the gas injector 53 are held at positions close to the lower surface of the substrate W. At this time, as indicated by the outlined arrow a51, the liquid nozzle 52 discharges the cleaning liquid toward the lower surface of the substrate W at a position in the vicinity of the lower-surface brush 51. Thus, the cleaning liquid that has been supplied to the lower surface of the substrate W from the liquid nozzle 52 is guided to a contact portion in which the lower-surface brush 51 and the substrate W are in contact with each other, whereby contaminants that have been removed from the back surface of the substrate W by the lower-surface brush 51 are washed away by the cleaning liquid. In this manner, in the lower-surface cleaning device 50, the liquid nozzle 52 is attached to the lifting-lowering supporter 54 together with the lower-surface brush 51. Thus, the cleaning liquid can be supplied efficiently to a portion to be cleaned in the lower surface of the substrate W by the lower-surface brush 51. Therefore, the consumption of the cleaning liquid is reduced, and excessive splashing of the cleaning liquid is suppressed.

Here, the upper surface 54u of the lifting-lowering supporter 54 is inclined downwardly in a direction away from the suction holder 21. In this case, in a case where the cleaning liquid including contaminants falls on the lifting-lowering supporter 54 from the lower surface of the substrate W, the cleaning liquid received by the upper surface 54u is guided in a direction away from the suction holder 21.

Further, when the lower surface of the substrate W is cleaned by the lower-surface brush 51, the gas injector 53 injects gas toward the lower surface of the substrate W at a position between the lower-surface brush 51 and the suction holder 21 as indicated by the outlined arrow a52 in the balloon of FIG. 10. In the present embodiment, the gas injector 53 is attached onto the lifting-lowering supporter 54 such that the gas injection port extends in the X direction. In this case, when gas is injected to the lower surface of the substrate W from the gas injector 53, a strip-shaped curtain extending in the X direction is formed between the lower-surface brush 51 and the suction holder 21. Thus, when the lower surface of the substrate W is cleaned by the lower-surface brush 51, the cleaning liquid including contaminants is prevented from being splashed toward the suction holder 21. Thus, when the lower surface of the substrate W is cleaned by the lower-surface brush 51, the cleaning liquid including contaminants is prevented from adhering to the suction holder 21, and the suction surface of the suction holder 21 is maintained clean.

While the gas injector 53 injects gas obliquely upwardly toward the lower-surface brush 51 from the gas injector 53 as indicated by the outlined arrow a52 in the example of FIG. 10, the present invention is not limited to this. The gas injector 53 may inject gas in the Z direction toward the lower surface of the substrate W from the gas injector 53.

Next, in the state of FIG. 10, when the cleaning of the lower-surface center region of the substrate W is completed, the rotation of the lower-surface brush 51 is stopped, and the lifting-lowering supporter 54 is lowered such that the cleaning surface of the lower-surface brush 51 is spaced apart from the substrate W by a predetermined distance. Further, discharging of the cleaning liquid from the liquid nozzle 52 to the substrate W is stopped. At this time, the injection of gas from the gas injector 53 to the substrate W continues.

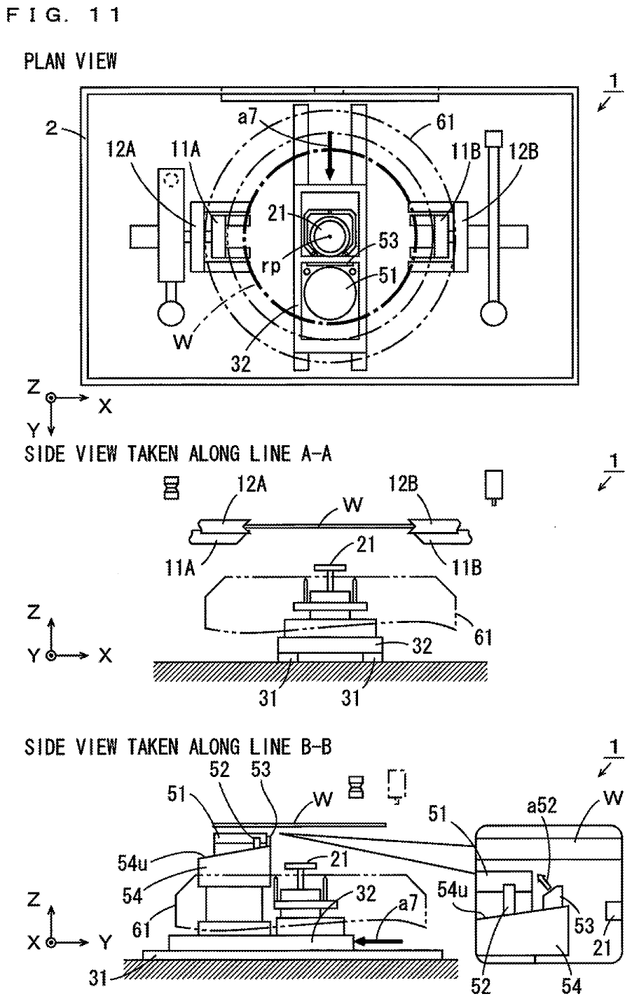

Thereafter, as indicated by the thick solid arrow a7 in FIG. 11, the mobile base 32 is moved rearwardly such that the suction holder 21 is located at the plane reference position rp. That is, the mobile base 32 is moved from the second horizontal position to the first horizontal position. At this time, the injection of gas from the gas injector 53 to the substrate W continues, so that the lower-surface center region of the substrate W is sequentially dried by the gas curtain.

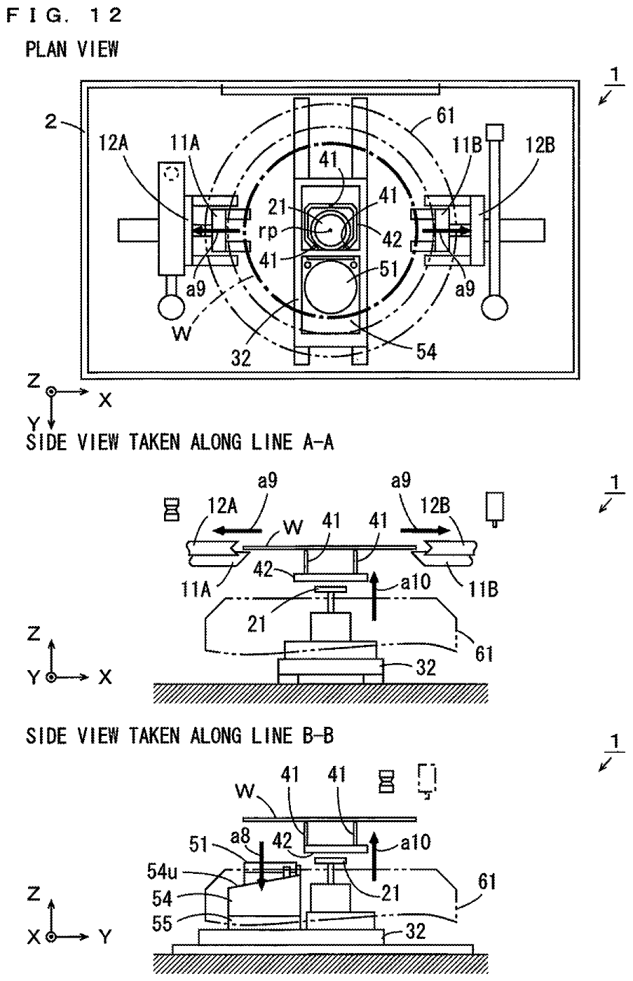

Next, as indicated by the thick solid arrow a8 in FIG. 12, the lifting-lowering supporter 54 is lowered such that the cleaning surface of the lower-surface brush 51 is located farther downwardly than the suction surface (upper end portion) of the suction holder 21. Further, as indicated by the thick solid arrows a9 in FIG. 12, the upper chucks 12A, 12B move away from each other such that the plurality of holding pieces of the upper chucks 12A, 12B are spaced apart from the outer peripheral end of the substrate W. At this time, the substrate W is being supported by the lower chucks 11A, 11B.

Thereafter, as indicated by the thick solid arrow a10 in FIG. 12, the pin coupling member 42 is lifted such that the upper end portions of the plurality of support pins 41 are located slightly farther upwardly than the lower chucks 11A, 11 B. Thus, the substrate W supported by the lower chucks 11A, 11B is received by the plurality of support pins 41.

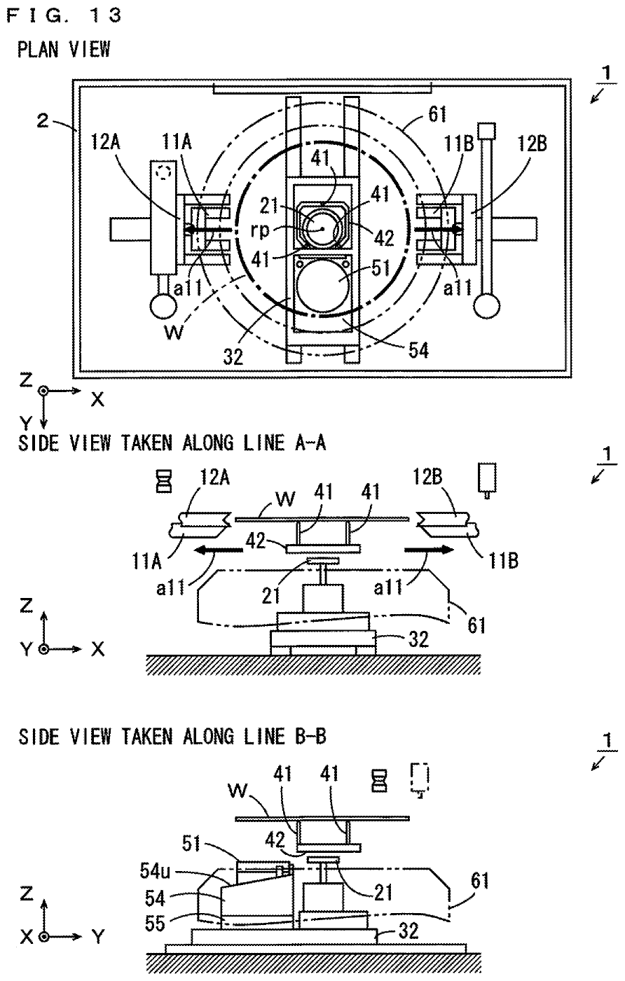

Next, as indicated by the thick solid arrows all in FIG. 13, the lower chucks 11A, 11B move away from each other. At this time, the lower chucks 11A, 11B move to positions at which the lower chucks 11A, 11B do not overlap with the substrate W supported by the plurality of support pins 41 in a plan view. Thus, both of the upper holding devices 10A, 10B return to the initial state.

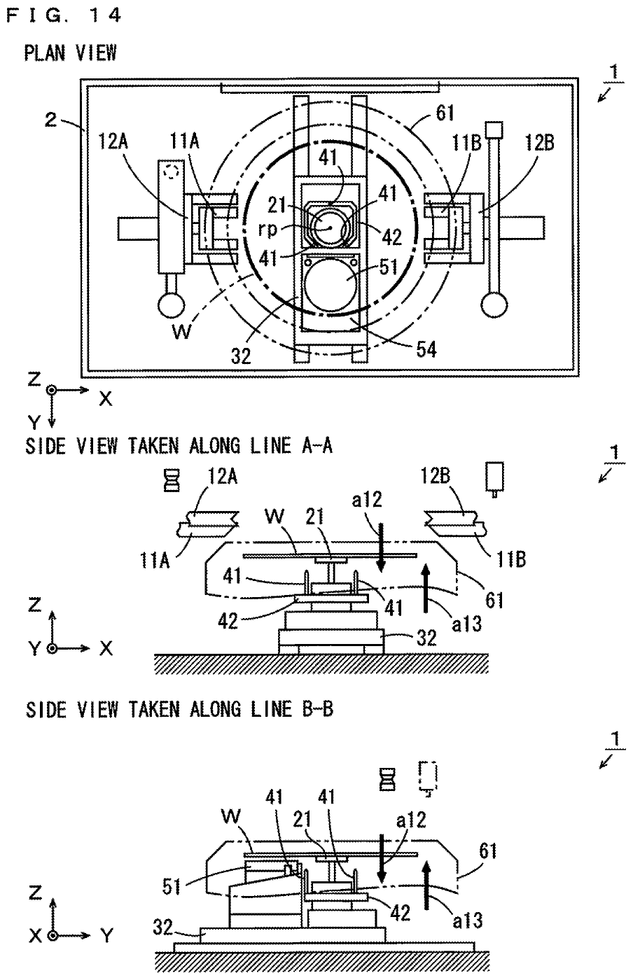

Next, as indicated by the thick solid arrow a12 in FIG. 14, the pin coupling member 42 is lowered such that the upper end portions of the plurality of support pins 41 are located farther downwardly than the suction holder 21. Thus, the substrate W supported on the plurality of support pins 41 is received by the suction holder 21. In this state, the suction holder 21 holds the lower-surface center region of the substrate W by suction. At the same time as the pin coupling member 42 is lowered or after the pin coupling member 42 is lowered, the cup 61 is lifted from the lower cup position to the upper cup position as indicated by the thick solid arrow a13 in FIG. 14.

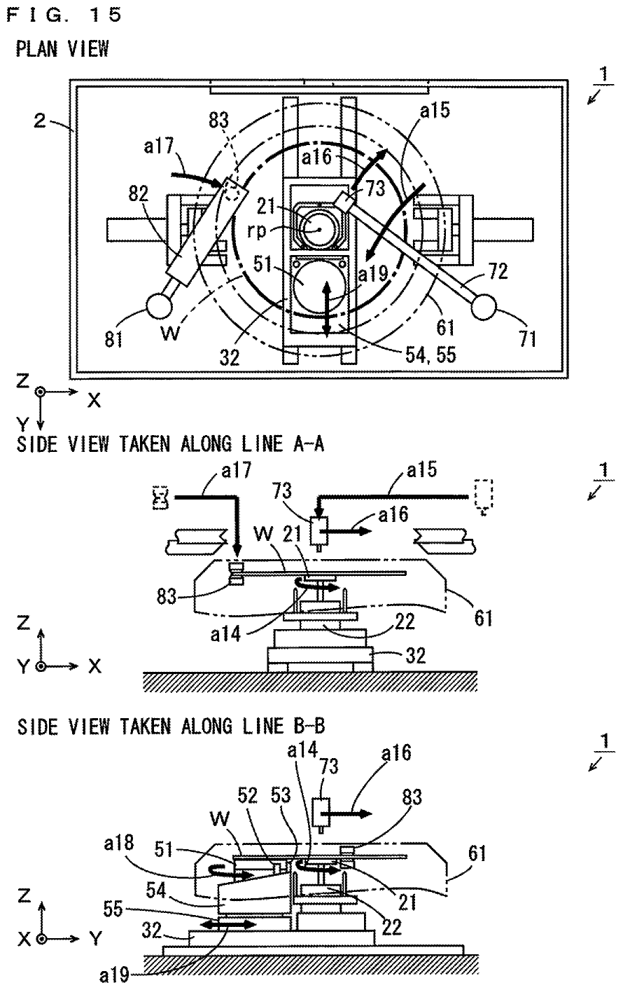

Next, as indicated by the thick solid arrow a14 in FIG. 15, the suction holder 21 rotates about the axis extending in the up-and-down direction (an axial center of the rotation shaft of the suction holding driver 22). Thus, the substrate W held by suction by the suction holder 21 is rotated in a horizontal attitude.

Next, the rotation support shaft 71 of the upper-surface cleaning device 70 is rotated and lowered. Thus, as indicated by the thick solid arrow a15 in FIG. 15, the spray nozzle 73 is moved to a position above the center of the substrate W, and the spray nozzle 73 is lowered such that the distance between the spray nozzle 73 and the substrate W is a predetermined distance. In this state, the spray nozzle 73 injects a fluid mixture of the cleaning liquid and gas to the upper surface of the substrate W. Further, the rotation support shaft 71 is rotated. Thus, as indicated by the thick solid arrow a16 in FIG. 15, the spray nozzle 73 moves outwardly (toward the point P1 of FIG. 4) from the center of the rotating substrate W. The fluid mixture is injected to the entire upper surface of the substrate W, so that the entire upper surface of the substrate W is cleaned.

Further, when the upper surface of the substrate W is cleaned by the spray nozzle 73, the rotation support shaft 81 of the end-portion cleaning device 80 is rotated and lowered. Thus, as indicated by the thick solid arrow a17 in FIG. 15, the bevel brush 83 is moved to a position above the outer peripheral end of the substrate W. Further, the bevel brush 83 is lowered such that the center portion of the outer peripheral surface of the bevel brush 83 comes into contact with the outer peripheral end (the point P2 of FIG. 4) of the substrate W. In this state, the bevel brush 83 is rotated (spins) about the axis extending in the up-and-down direction. Thus, contaminants adhering to the outer peripheral end of the substrate W are physically stripped by the bevel brush 83. The contaminants that have been stripped from the outer peripheral end of the substrate W are washed away by the cleaning liquid of the fluid mixture injected from the spray nozzle 73 to the substrate W.

Further, when the upper surface of the substrate W is cleaned by the spray nozzle 73, the lifting-lowering supporter 54 is lifted such that the cleaning surface of the lower-surface brush 51 comes into contact with the lower-surface outer region of the substrate W. At this time, the lower-surface brush 51 is located opposite to the spray nozzle 73 and the bevel brush 83 with the straight line L2 of FIG. 4 located between the lower-surface brush 51, and the spray nozzle 73 and the bevel brush 83. Further, as indicated by the thick solid arrow a18 in FIG. 15, the lower-surface brush 51 is rotated (spins) about the axis extending in the up-and-down direction. Further, the liquid nozzle 52 discharges the cleaning liquid toward the lower surface of the substrate W, and the gas injector 53 injects the gas toward the lower surface of the substrate W. Thus, it is possible to clean the entire lower-surface outer region of the substrate W held by suction and rotated by the suction holder 21 using the lower-surface brush 51.

The rotation direction of the lower-surface brush 51 may be opposite to the rotation direction of the suction holder 21. In this case, the entire lower-surface outer region of the substrate W can be cleaned efficiently. In the present embodiment, in a plan view, the rotation direction of the suction holder 21 is clockwise, and the rotation direction of the lower-surface brush 51 is counterclockwise. In a case in which the lower-surface brush 51 is not relatively large, the movement supporter 55 may advance and retreat between the proximal position and the distal position on the mobile base 32 as indicated by the thick solid arrow a19 in FIG. 15. Also in this case, it is possible to clean the entire lower-surface outer region of the substrate W held by suction and rotated by the suction holder 21 using the lower-surface brush 51.

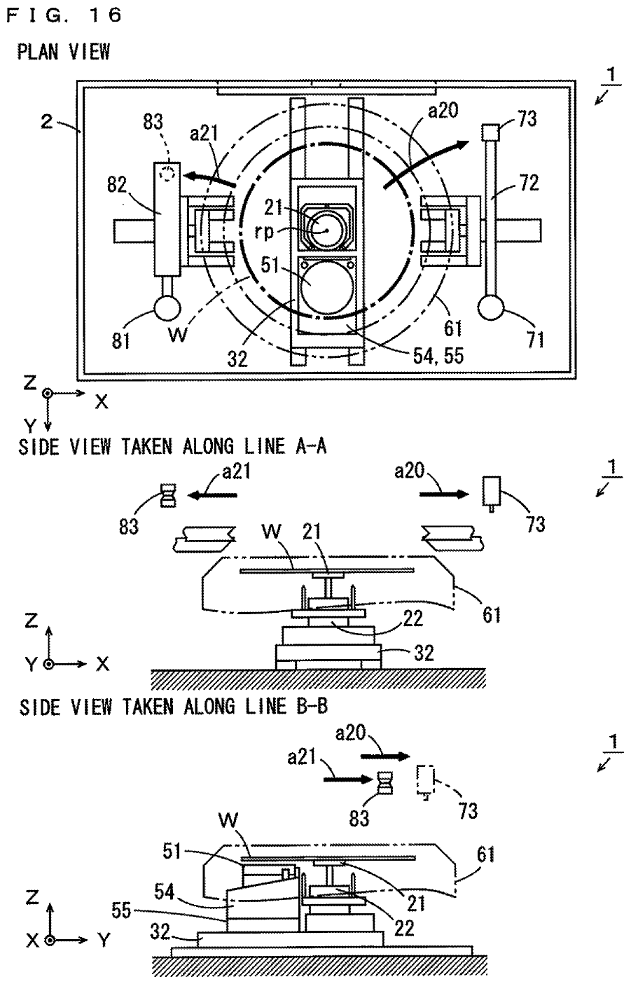

Next, when cleaning of the upper surface, the outer peripheral end and the lower-surface outer region of the substrate W is completed, injection of the fluid mixture from the spray nozzle 73 to the substrate W is stopped. Further, as indicated by the thick solid arrow a20 in FIG. 16, the spray nozzle 73 is moved to a position near one side of the cup 61 (the position in the initial state). Further, as indicated by the thick solid arrow a21 in FIG. 16, the bevel brush 83 is moved to a position near the other side of the cup (the position in the initial state). Further, the rotation of the lower-surface brush 51 is stopped, and the lifting-lowering supporter 54 is lowered such that the cleaning surface of the lower-surface brush 51 is spaced apart from the substrate W by a predetermined distance. Further, the discharging of the cleaning liquid from the liquid nozzle 52 to the substrate W and the injection of gas from the gas injector 53 to the substrate W are stopped. In this state, the suction holder 21 is rotated at a high speed, so that the cleaning liquid adhering to the substrate W is shaken off, and the entire substrate W is dried.

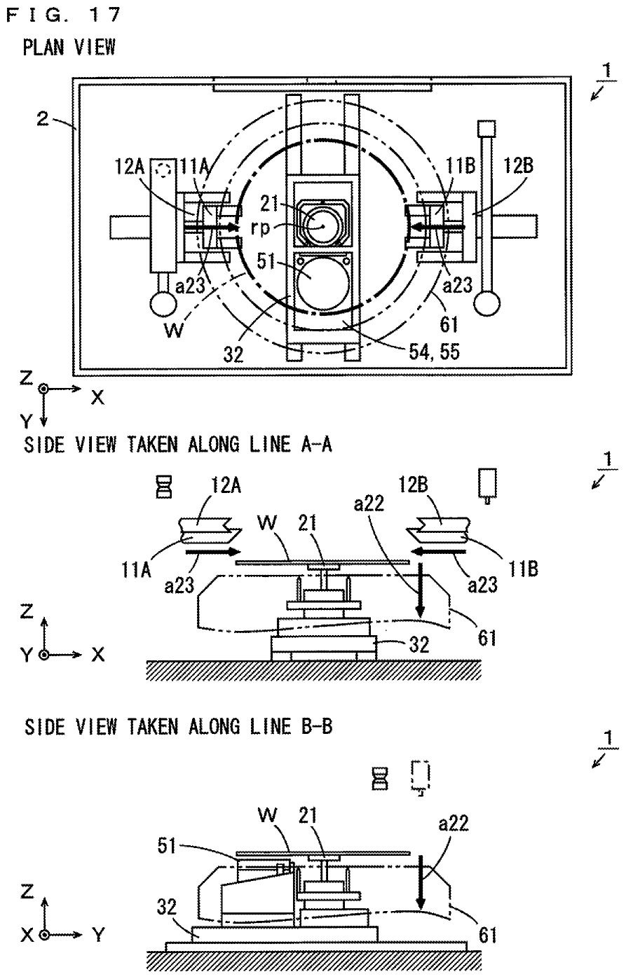

Next, as indicated by the thick solid arrow a22 in FIG. 17, the cup 61 is lowered from the upper cup position to the lower cup position. Further, as indicated by the thick solid arrows a23 in FIG. 17, the lower chucks 11A, 11B move closer to each other to a position at which the lower chucks 11A, 11 B can support a new substrate Win preparation for the new substrate W being carried into the unit casing 2.

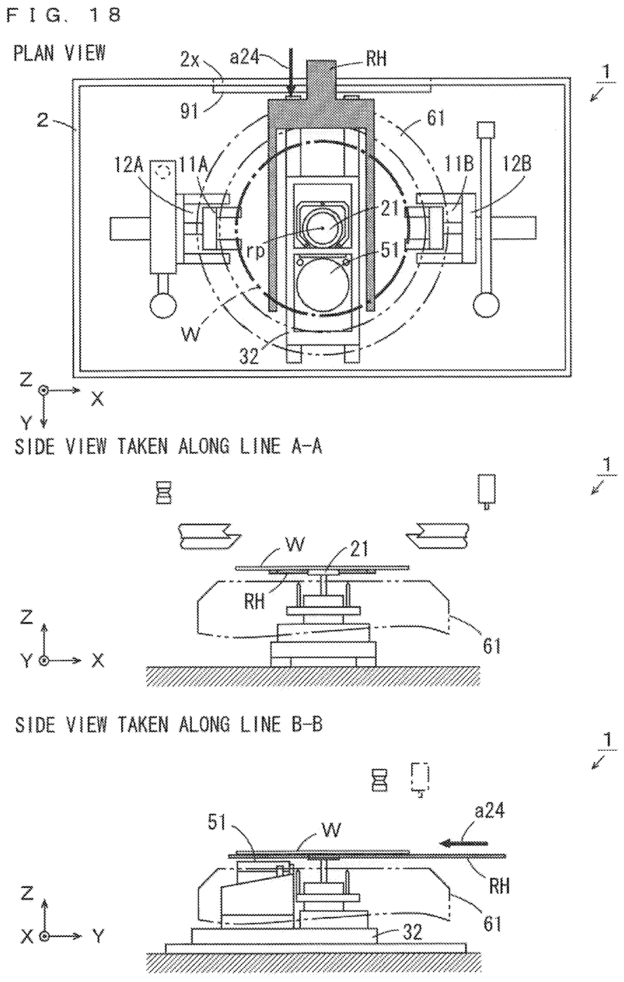

Finally, the substrate W is carried out from the unit casing 2 of the substrate cleaning device 1. Specifically, the shutter 91 opens the inlet-outlet port 2x immediately before the substrate W is carried out. Thereafter, as indicated by the thick solid arrow a24 in FIG. 18, the hand (substrate holder) RH of the substrate transferring robot (not shown) enters the unit casing 2 through the inlet-outlet port 2x. Subsequently, the hand RH receives the substrate Won the suction holder 21 and exits from the inlet-outlet port2x. After the hand RH exits, the shutter 91 closes the inlet-outlet port 2x.

(4) Effects

In the substrate cleaning device 1 according to the present embodiment, the spray nozzle 73, the bevel brush 83 and the lower-surface brush 51 are arranged to be relatively largely spaced apart from one another. Therefore, even in a case in which the upper surface, the outer peripheral end and the lower surface of a substrate W are respectively cleaned by the spray nozzle 73, the bevel brush 83 and the lower-surface brush 51 at the same time, contaminants generated from any of the cleaners hardly adhere to another cleaner. Therefore, it is not necessary to provide a plurality of devices that respectively clean a plurality of portions of a substrate W, and it is not necessary to move the substrate W among the plurality of devices either. As a result, it is possible to efficiently clean the substrate W while preventing an increase in size of the substrate cleaning device 1.

Further, the spray nozzle 73 cleans the upper surface of the substrate W by scanning from the center of the substrate W toward the point P1 in a plan view. In this case, contaminants generated from the spray nozzle 73 hardly adhere to the bevel brush 83 or the lower-surface brush 51. Similarly, contaminants generated from the bevel brush 83 or the lower-surface brush 51 hardly adhere to the spray nozzle 73. Therefore, the upper surface of the substrate W can be more efficiently cleaned by the spray nozzle 73 with a simple configuration. Further, because the lower-surface brush 51 is relatively large, the lower surface of the substrate W can be efficiently cleaned.

(5) Other Embodiments

(a) While the lower-surface outer region of the substrate W is cleaned in the lower holding device 20 after the lower-surface center region of the substrate W is cleaned in the upper holding devices 10A, 10B in the above-mentioned embodiment, the embodiment is not limited to this. The lower-surface center region of the substrate W may be cleaned in the upper holding devices 10A, 10B after the lower-surface outer region of the substrate W is cleaned in the lower holding device 20. Further, the lower-surface center region of the substrate W does not have to be cleaned. In this case, the substrate cleaning device 1 does not include the upper holding devices 10A, 10B or the receiving-transferring device 40.

(b) While the upper surface of the substrate W is cleaned by scanning of the spray nozzle 73 from the center P0 to the point P1 of the substrate W in a plan view in the above-mentioned embodiment, the embodiment is not limited to this. The spray nozzle 73 may clean the upper surface of the substrate W by scanning from the point P1 toward the center P0 of the substrate W in a plan view. While the upper surface of the substrate W is cleaned with use of the spray nozzle 73 that injects a fluid mixture, the embodiment is not limited to this. The upper surface of the substrate W may be cleaned with use of a brush or may be cleaned with use of a rinse nozzle that discharges a rinse liquid.

(c) While the substrate cleaning device 1 includes the controller 9 in the above-mentioned embodiment, the embodiment is not limited to this. In a case in which the substrate cleaning device 1 is configured to be controllable by an external information processing apparatus, the substrate cleaning device 1 does not have to include the controller 9.

(6) Correspondence Relationship Between Respective Components of Claims and Respective Portions of Embodiments

In the following paragraphs, non-limiting examples of correspondences between various elements recited in the claims below and those described above with respect to various preferred embodiments of the present invention are explained. As each of constituent elements recited in the claims, various other elements having configurations or functions described in the claims can be also used.

In the above-mentioned embodiment, the substrate W is an example of a substrate, the suction holder 21 is an example of a substrate holder, the points P1 to P3 are respectively examples of first to third points, the spray nozzle 73, the bevel brush 83 and the lower-surface brush 51 are respectively examples of first to third cleaners, the straight lines L1 to L5 are respectively examples of first to fifth straight lines, the angles θ1 to θ3 are respectively examples of first to third angles, and the substrate cleaning device 1 is an example of a substrate cleaning device.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

I/We claim:

1. A substrate cleaning device comprising:
a substrate holder that holds a circular substrate in a horizontal attitude;
a first cleaner that cleans an upper surface of the substrate by scanning above the substrate to pass through a first point in an outer edge of the substrate in a plan view;
a second cleaner that cleans an outer peripheral end of the substrate by coming into contact with a second point in the outer edge of the substrate in a plan view; and
a third cleaner that cleans a lower surface of the substrate, wherein
a virtual first line that passes through the first point and the second point and a virtual second straight line that passes through a center of the substrate and is parallel to the first straight line, and
the third cleaner is arranged below the substrate and opposite to the first cleaner and the second cleaner with the second straight line located between the third cleaner, and the first cleaner and the second cleaner.

2. The substrate cleaning device according to claim 1, wherein
a virtual third straight line extending from a center of the substrate to a geometric center of the third cleaner in a plan view and a third point in an outer edge of the substrate through which the third straight line passes in a plan view are further defined, and
the first cleaner, the second cleaner and the third cleaner are arranged such that the center of the substrate is located in a triangular region having the first point, the second point and the third point as vertexes.

3. The substrate cleaning device according to claim 2, wherein
a virtual fourth straight line extending from a center of the substrate toward the first point in a plan view and a virtual fifth straight line extending from the center of the substrate toward the second point in a plan view are further defined, and
each of a first angle between the third straight line and the fourth straight line and a second angle between the fourth straight line and the fifth straight line and a third angle between the fifth straight line and the third straight line is equal to or larger than 80 degrees.

4. The substrate cleaning device according to claim 3, wherein
each of the first angle, the second angle and the third angle is equal to or larger than 90 degrees.

5. The substrate cleaning device according to claim 3, wherein
the first angle is larger than the second angle.

6. The substrate cleaning device according to claim 3, wherein
the third angle is larger than the second angle.

7. The substrate cleaning device according to claim 1, wherein
the first cleaner cleans an upper surface of the substrate by scanning from a center of the substrate toward the first point in a plan view.

8. The substrate cleaning device according to claim 1, wherein
each of the substrate holder and the third cleaner has a circular outer shape, and
a diameter of the third cleaner is larger than a diameter of the substrate holder.

9. The substrate cleaning device according to claim 1, wherein
the third cleaner has a circular outer shape, and
a diameter of the third cleaner is larger than ⅓ of a diameter of the substrate.
